(19) United States
(12) Patent Application Publication
(10) Pub. No.: US 2005/0255636 A1
(43) Pub. Date: Nov. 17, 2005

(54) Microtools for package substrate patterning

(76) Inventor: Daewoong Suh, Phoenix, AZ (US)

Correspondence Address: INTEL/BLAKELY, 12400 WILSHIRE BOULEVARD, SEVENTH FLOOR, LOS ANGELES, CA, 90025-1030, US

(21) Appl. No.: 11/180,437

(22) Filed: Jul. 12, 2005

Related U.S. Application Data
(62) Division of application No. 10/816,535, filed on Mar. 31, 2004.

(51) Int. Cl. H01L 21/44

(52) U.S. Cl. 438/125

(57) ABSTRACT

An improved microtool for patterning package substrates is enclosed. The microtool comprises a base portion including a pattern to pattern a substrate and an electroless nickel layer deposited over the base portion. The base portion may comprise pure nickel, a nickel alloy, or copper. The electroless nickel layer increases the hardness of the microtool, as well as improving the corrosion resistance and the lubricity of the tool. The microtool may be formed by creating a mold, activating the mold, depositing an electroless nickel layer over the mold, electroplating the base portion over the electroless nickel layer, and removing the mold.

This is a Divisional application of Ser. No. 10/816,535 filed Mar. 31, 2004, which is presently pending.

### FIELD OF THE INVENTION

The invention relates generally to semiconductor processing, and specifically to tools for forming package substrates.

### BACKGROUND

A semiconductor die contains the active elements that comprise an integrated circuit such as a microprocessor. Semiconductor dies are typically very small and have a large number of signal and power contacts. Because of the small size of the die, a package substrate is typically needed to effectively enlarge the area over which connections may be made with the die. The die is usually mounted to one side of the package substrate, while the other side is coupled to several interconnect devices, such as pins, balls, etc., which then allow the completed package to be mounted into a socket or another device on a printed circuit board (PCB). Interconnects within the package substrate electrically connect the die to the interconnect devices.

A package substrate typically includes a metal or organic core, and dielectric layers on top of the core that insulate conductors forming interconnects. The process of forming the package substrate typically begins with providing the core, and forming a dielectric layer on either side of the core. The dielectric layers may then be etched to form troughs, which will then be filled with a conductive material, such as copper, to form an interconnect. More dielectric layers may be formed on top of the package substrate as necessary to provide adequate communication with the die. The dielectric layers are typically laser etched to form the troughs for the interconnects. The laser etching process can be imprecise and time consuming, and the equipment required for the laser etching process is expensive.

More recently, microtools have been developed to impress a pattern into the package substrate. A microtool is a small tool that is patterned so that when it is pressed against a layer, the pattern will be impressed in the layer. Microtools are now typically formed from pure nickel. One approach of increasing the hardness of pure nickel microtools is to add sulfur containing organic additives. These additives increase the hardness of the tool, thereby reducing wear. However, the co-deposited sulfur can create sulfur embrittlement during elevated temperature exposure

### BRIEF DESCRIPTION OF THE DRAWINGS

One or more embodiments of the present invention are illustrated by way of example and not limitation in the figures of the accompanying drawings, in which like references indicate similar elements and in which:

FIG. 1A illustrates an overhead view of a microtool;

FIG. 1B illustrates a side view of the microtool;

FIG. 2 illustrates a process forming a microtool according to an embodiment of the inventions;

FIG. 3A illustrates a mold that is patterned to mirror the desired resulting microtool;

FIG. 3B illustrates an electroless nickel layer deposited over a mold;

FIG. 3C illustrates a metal layer deposited over an electroless nickel layer;

FIG. 3D illustrates a finished micrtool removed from the mold;

FIG. 4 illustrates a process for imprinting a substrate using a microtool;

FIG. 5A illustrates a substrate core;

FIG. 5B illustrates a package substrate including a core and dielectric layer 504 deposited on either side of the core;

FIG. 5C illustrates a patterned dielectric layer;

FIG. 5D illustrates a deposited seed layer;

FIG. 5E illustrates metal deposited over the dielectric layer; and

FIG. 5F illustrates interconnects formed in the dielectric layer.

### DETAILED DESCRIPTION

Described herein is an improved microtool for package substrate patterning and a method for forming the microtool. In the following description, numerous specific details are set forth. However, it is understood that embodiments may be practiced without these specific details. For example, well-known equivalent materials may be substituted in place of those described herein, and similarly, well-known equivalent techniques may be substituted in place of the particular semiconductor processing techniques disclosed. In other instances, well-known structures and techniques have not been shown in detail in order to not obscure the understanding of this description.

According to an embodiment of the invention, a microtool comprises a base portion including a pattern to impress an interconnect substructure on substrate, and an electroless nickel layer deposited over the base portion. The electroless nickel layer increases the overall hardness of the microtool, thereby increasing the life of the tool. The electroless nickel layer also has a lower coefficient of friction than pure nickel, thereby increasing the microtool's lubricity and reducing the amount of the patterned layer that adheres to the microtool. The base portion may comprise pure nickel or a nickel alloy such as a nickel-cobalt (Ni—Co) alloy, a nickel-manganese (Ni—Mn) alloy, and a nickel-iron (Ni—Fe) alloy.

The microtool may be formed by creating a mold comprising photoresist, silicon, or any other appropriate material that can be patterned, and using photolithography to pattern the mold. The electroless nickel layer is deposited over the mold using well-known electroless deposition techniques. After the electroless nickel layer is deposited, the base portion may be deposited over the mold with an electroplating process using the electroless nickel layer as a seed layer. The mold may then be manually or chemically removed from the microtool, and the process for forming the microtool is complete. Alternatively, an existing pure nickel microtool may have an electroless nickel layer deposited over it, thereby forming a microtool having increased overall hardness.

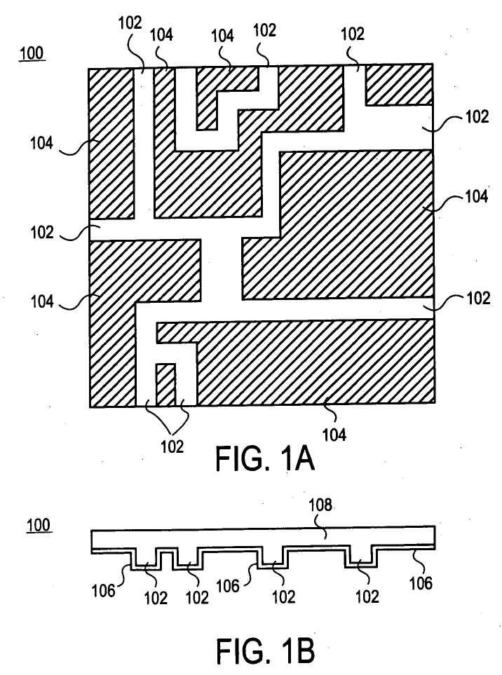

FIGS. 1A and 1B illustrate a microtool according to one embodiment of the invention. FIG. 1A illustrates an overhead view of a microtool 100 and FIG. 1B illustrates a cross-sectional view of the microtool 100. As can be seen in FIG. 1A, the microtool 100 includes raised portions 102 and recessed portions 104. When pressure is applied to the backside of the microtool 100, and the microtool 100 is pressed against a dielectric or other soft layer, the raised portions 102 will impress a pattern in the dielectric layer. The raised portions 102 define the features that will be impressed upon a package substrate. According to one embodiment, the microtool 102 may pattern a typical feature size of 10-100 μm. The pressure may be supplied by a pushing jig or any other appropriate device. The pattern formed in the dielectric layer can then be filled with a conductive material to form interconnects. This process will be explained below. The microtool 100 should be patterned such that the areas where interconnects are to be formed on the package substrate correspond to the raised areas 102. It is understood that the microtool 100 may include a pattern for patterning a single package substrate, however, in practice the microtool 100 may include a pattern to pattern several package substrates at once.

As shown in FIG. 1B, the surface of the microtool 100 is coated with an electroless nickel layer 106. An electroless nickel-phosphorus alloy typically has a hardness value (HV) of 500 on the Vickers Hardness Scale. The electroless deposition process produces a hard layer because of the amorphous, non-crystalline structure that results from the chemical deposition. Pure nickel, in contrast, is polycrystalline. In an alternative embodiment, the microtool 100 may be annealed, for example at 400° C. for 1 hour, to increase the hardness of the layer 106. An annealed layer 106 may have a hardness value of 1100 or more. As mentioned above, wear resistance increases with increased hardness. Therefore, by increasing the hardness of the microtool 100, wear resistance increases and the microtool will last longer and form better impressions on a package substrate. An electroless nickel-phosphorus alloy heat treated for 1 hour will loose only between 1 and 4 milligrams per 1000 cycles according to the Taber Wear Index, and an electroless nickel-boron alloy will typically have increased wear resistance compared to an electroless nickel-phosphorus alloy.

According to a further embodiment of the invention, the electroless nickel layer 106 may be a composite. The electroless nickel layer 106 may include a reinforcing constituent such as silicon carbide, aluminum oxide (Al₂O₃), synthetic diamond particles, or polytetrafluoroethylene (PTFE). The reinforcing constituent increases the hardness of the electroless nickel layer. For example, an electroless nickel and silicon carbide composite typically has a hardness value of 1300. Using PTFE as a reinforcing constituent further increases the lubricity of the electroless nickel layer 106. Such electroless nickel composites are commonly known and widely available. The increased hardness of the composite electroless nickel will further reduce wear, thereby increasing the life of the microtools and improving their printing accuracy.

The electroless nickel layer also provides superior corrosion protection for the microtool 100, as well as decreasing the coefficient of friction of the microtool 100. The coefficient of friction of the microtool is reduced because the phosphorous and boron components of the electroless nickel layer provide natural lubricity that is not present with pure nickel. The result of reducing the coefficient of friction in the microtool 100 is increased lubricity, which reduces the incidence of the dielectric material adhering to the microtools. This, in turn, reduces the need to clean the microtool 100 after processing, as well as creating more precise and defined impressions, and as a result more accurate interconnect structures in the dielectric layer. The overall result is more precise impressions than can be had with pure nickel microtools.

The base portion 108 of the microtool 100 is the portion of the microtool underlying the electroless nickel layer 106. The base portion 108 may be a material that is ductile and easy to process. The base portion 108 may be pure nickel or a nickel alloy, such as a nickel-cobalt alloy, a nickel-manganese alloy, or a nickel-iron alloy. The base portion 108 may also comprise another metal such as copper. Since the base portion 108 does not contact the package substrate during processing, the additional hardness of the electroless nickel layer is not needed. However, the base portion 108 may be formed from a nickel alloy such as those described above to further increase the overall hardness of the microtool 100 if desired.

Other characteristics of the microtool 100 include increased elevated temperature stability compared to pure nickel and nickel with sulfur additives. Since the microtool 100 will often be subjected to high heat as a result of the imprinting process, the better heat resistance of the electroless nickel layer 106 will extend the life of the microtool 100. The electroless nickel layer 106 also provides better coating uniformity, since the electroless deposition process is a chemical process. The better uniformity allows for smaller feature size on the microtool, and more precise features overall. This is especially important where the microtool 100 includes complex features. Finally, the electroless deposition process is well known, thereby allowing easy high volume manufacturing of the microtool 100.

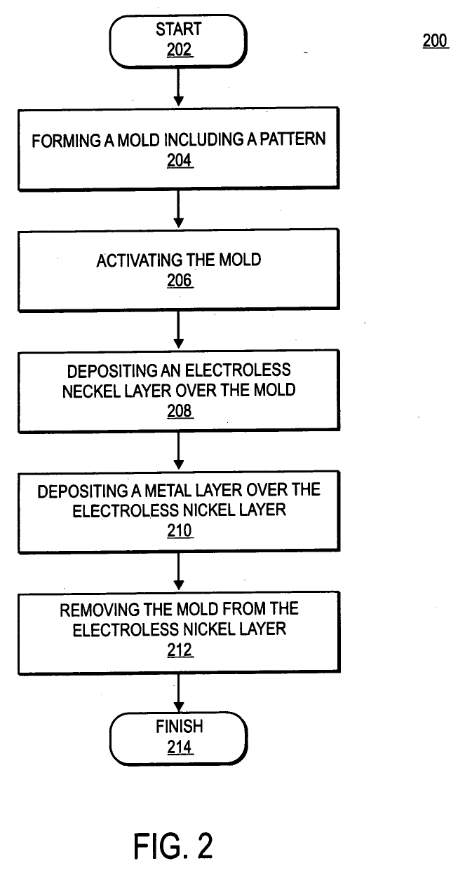

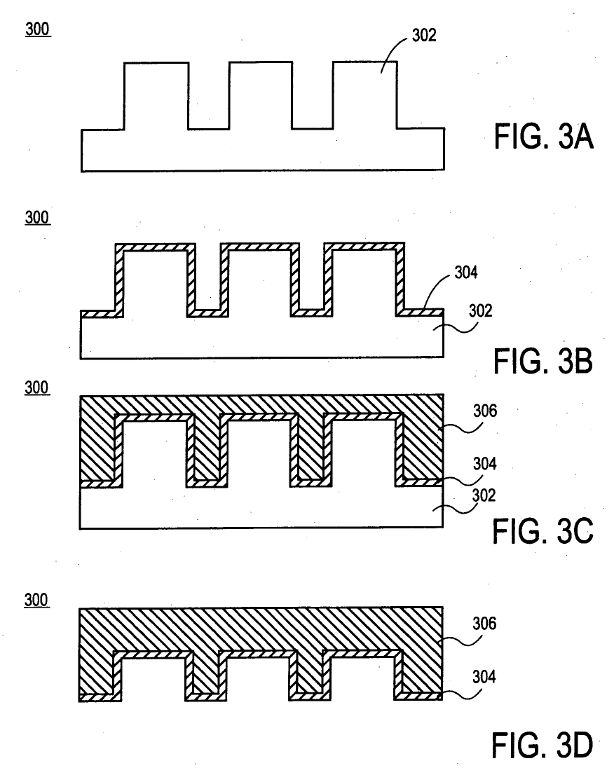

FIG. 2 illustrates a process 200 for forming a microtool 100 according to an embodiment of the invention. FIGS. 3A-3D illustrate the formation of a microtool described in FIG. 2. The process 200 starts in start block 202. In block 204, a mold including a pattern is formed. FIG. 3A illustrates a mold 302 that is patterned to mirror the desired microtool. Since the microtool will be formed on the mold 302, the mold 302 is created using a pattern complementary to that of the desired microtool.

The mold 302 may comprise photoresist, silicon, or other materials that can be patterned. If the mold 302 is photoresist, the mold 302 may be patterned using common photolithographic techniques. For example, a deposited layer of photoresist may be exposed to light through a mask that includes the pattern. After the layer of photoresist has been exposed, if the photoresist is a positive photoresist, the exposed areas will soften, and the softened areas may be removed using a specifically chosen selective etch. After the resist layer has been etched, the mold 302 has been formed. A similar process can be used to form the mold 302 from silicon or other materials, however, a layer of photoresist typically must be deposited on top of the layer of silicon to perform the photolithography. After the resist has been deposited over the silicon, the resist is exposed through a mask forming a pattern, and the exposed portions of the resist are removed. The silicon underlying the removed resist is then etched using a selective etch chosen to remove the exposed silicon. After the silicon has been etched, the photoresist is removed, and the mold 302 has been formed.

In block 206, the mold 302 is activated using an activation solution, which may be a gold, palladium, and etc. activation solution. The mold 302 is activated to attract the nickel ions in the plating bath to the activated areas of the mold 302. Any activation solution appropriate for the chosen plating bath may be used. The plating bath may be any appropriate bath, such as any one of the several commercially available plating baths. In block 208, an electroless nickel layer is deposited over the mold 302. The mold 302 is immersed in the plating bath, and the activated areas of the mold 302 will attract nickel ions in the bath, thereby forming an electroless nickel layer on the surface of the mold 302. The amount of time the mold 302 is left in the plating bath determines the thickness of the layer. Generally, the longer the mold 302 is in the bath, the thicker the layer will be. Since the electroless plating process is chemical, the electroless nickel layer will have good uniformity, thereby providing better definition of small features. Also, the electroless plating process forms an amorphous, non-crystalline structure which is inherently strong.

FIG. 3B illustrates an electroless nickel layer 304 deposited over a mold 302. After the mold 302 is activated, it is placed in an electroless plating bath. Nickel ions in the plating bath are attracted to the activated portions of the mold 302. The electroless plating process produces a strong and uniform layer 304 on the mold 302. The thickness of the resulting electroless nickel layer 304 will increase the longer the mold 302 is left in the electroless-plating bath. According to one embodiment of the invention, the electroless nickel layer 304 should have a thickness of less than 10 microns to avoid making the layer 304 brittle.

In block 210, a metal layer is deposited over the electroless nickel layer 304. FIG. 3C illustrates a metal layer 306 deposited over an electroless nickel layer 304. The metal layer 306 may be nickel or nickel alloy, which may be deposited using an electroplating process. According to one embodiment, since the electroless nickel layer 304 may become too brittle if it is applied to thickly, another metal is used for the base of the microtool. The electroplating process is similar to the electroless plating process in that the mold 302 is deposited in a plating bath, however the mold 302 is not chemically activated for the electroplating process. Instead, the ions in the plating bath are charged, and will be attracted to the electroless nickel layer 304 when a current is driven through the electroless nickel layer 304. The resulting metal layer 306 is not as hard as the electroless nickel layer 304, however it is more pliant, and therefore less likely to break. Since only the surface of the microtool, which is coated with the electroless nickel layer 304, will be in contact with the package substrate, the remainder of the microtool need not be as hard, and a less brittle material may be used to reduce the incidence of tool breakage. In another embodiment, a nickel alloy such as one of the alloys mentioned above may be used in place of the electroplated pure nickel. The nickel alloy may also be deposited using an electroplating process.

In block 212, the mold 302 is removed from the electroless nickel layer 304. After the mold 302 is removed, the remaining electroless nickel layer 304 and metal layer 306 will form the microtool. FIG. 3D illustrates a finished microtool 300 removed from the mold 302. The materials comprising the mold 302 are much softer than the materials comprising the microtool, and can typically be easily removed either manually or chemically. Also, since the electroless nickel layer 304 has a low coefficient of friction, the mold 302 will not adhere very strongly to the electroless nickel layer 304. The mold 302 may be removed manually, for example, by hand or using a jig. Portions of the mold 302 may remain on the electroless nickel layer 304 after the rest of the mold 302 is manually removed. These portions can be removed using a chemical agent that dissolves photoresist, silicon, or whatever material was used for the mold 302. In block 214, the process 200 is finished. The result is a microtool 300 that exhibits increased hardness, and as a result reduced wear, thereby increasing the life of the microtool 300 and dramatically reducing the cost of the microtool 300 as well as increasing the accuracy of the package substrate imprinting process.

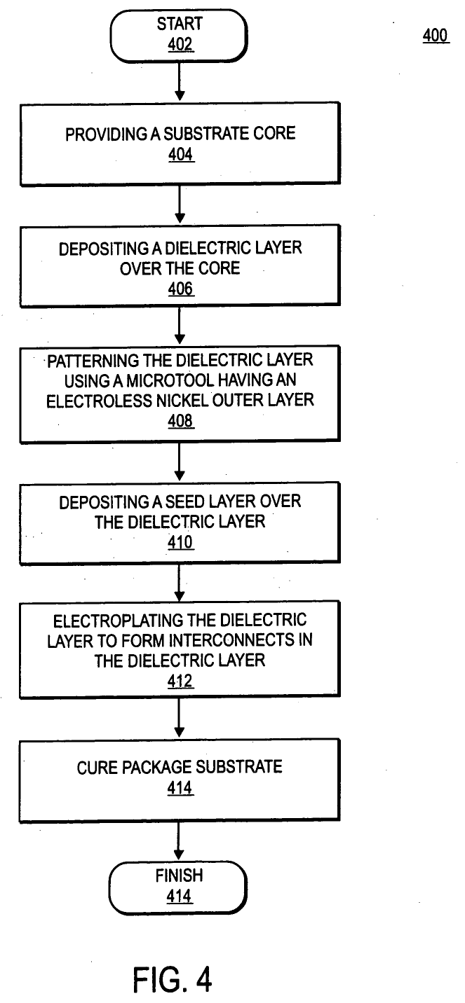

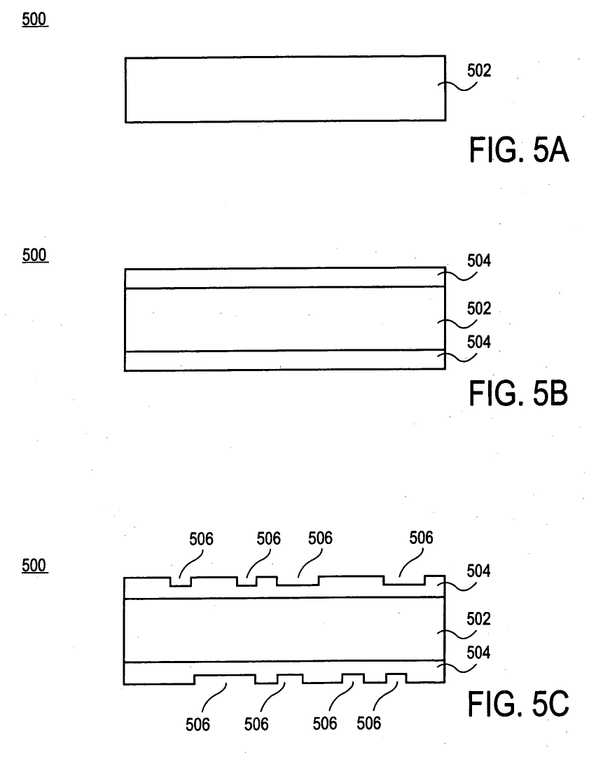

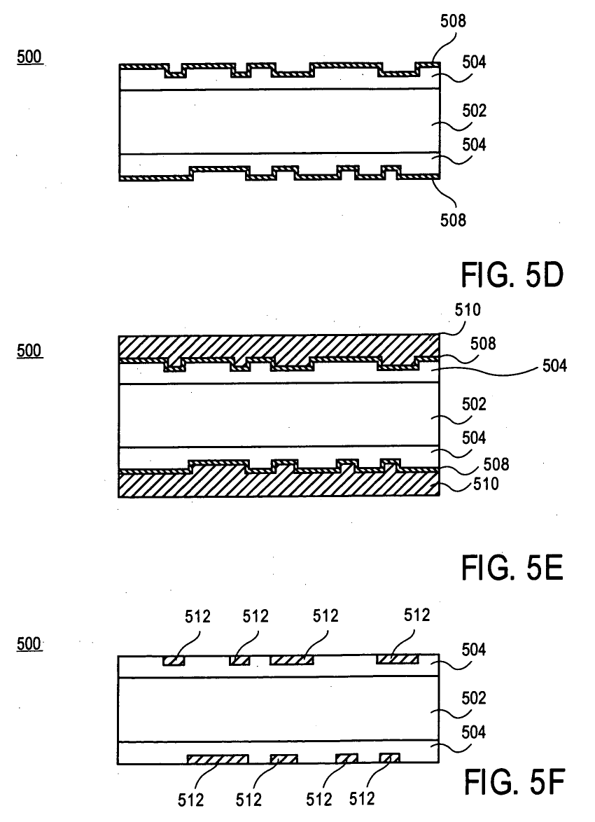

FIG. 4 illustrates a process 400 for imprinting a substrate using a microtool. FIGS. 5A-F illustrate the process described in FIG. 4. The process 400 starts in start block 402. In block 404, a substrate core is provided. FIG. 5A illustrates a substrate core 502. The substrate core 502 may be a metallic or organic material that has been chosen to provide strength for the package substrate 500. The core 502 may include one or more vias to facilitate electrical communication between the top side and the bottom side of the package substrate 500. The vias (not shown) may be formed by drilling holes in the core 502, and filling the holes with a conductive material such as copper. The vias can then connect with the interconnects that will be formed in the dielectric layers. The vias facilitate communication between the semiconductor die and the interconnect devices in the semiconductor package.

In block 406, a dielectric layer is deposited over the core 502. FIG. 5B illustrates a package substrate including a core 502 and dielectric layer 504 deposited on either side of the core 502. The dielectric layers 504 may be epoxy or another appropriate material, and may be deposited using spin-on deposition, etc. The material comprising the dielectric layers 504 should be deformable by the microtool 100.

In block 408, the dielectric layers 504 are patterned using a microtool having an electroless nickel outer layer. FIG. 5C illustrates a patterned dielectric layer 504. The indentations 506 in the dielectric layer 504 are formed by pressing the microtool against the dielectric layer 504. As mentioned above, the microtool 100 includes an electroless nickel layer 306 to increase hardness and reduce coefficient of friction to provide better lubricity.

In block 410, a seed layer is deposited over the dielectric layer 504. FIG. 5D illustrates a deposited seed layer 508. The seed layer 508 will be used during the electroplating process to provide current to areas of the dielectric layer that will be electroplated. The seed layer 508 may comprise any appropriate conductive material, such as copper, titanium, etc, and may be deposited using any appropriate process including sputtering, chemical vapor deposition (CVD), etc.

In block 412, the dielectric layer 504 is electroplated to form interconnects in the dielectric layer 504. FIG. 5E illustrates metal 510 deposited over the dielectric layer 504. The metal 510 will form interconnects to communicate with the semiconductor die. The metal 510 may be any conductive material, including aluminum, copper, etc. The metal 510 may be deposited with the electroplating process described above, using the seed layer 508 to deliver current and attract the metal to the substrate 500. The metal 510 is polished back to the dielectric layer 504 to isolate and form the interconnects 512. FIG. 5F illustrates several isolated interconnects 512. The interconnects 512 allow for communication with the die. The metal 510 can be polished back using chemical mechanical polishing (CMP) or any other appropriate method for planarizing the substrate 500 until the remaining metal 510 is electrically isolated.

The interconnects 512 may also be coupled to vias which connect with vias in the core 502 to allow for communication between interconnects formed on the top of the package substrate 500 and interconnects attached to the bottom of the package substrate 500. More dielectric layers may be deposited on top of the dielectric layers 504 and the interconnects 512 to create more layers of interconnects. The top dielectric layer of the package substrate 500 may have openings formed in it to create pads coupled to vias that are to contact ball grid array (BGA) balls or other interconnects between the die and the package substrate 500. In block 414, the package substrate 500 is cured to finish the processing of the dielectric layers 504. In block 416, the process 400 is complete, and the package substrate 500 has been formed.

According to an alternate embodiment of the invention, an electroless nickel layer may be deposited over an existing pure nickel microtool to increase the hardness of the microtool. For example, a pure nickel microtool may be formed using known processes. An example of such a process includes forming a mold, depositing a seed layer such as gold, copper, etc. over the mold, and electroplating the tool over the mold. The microtool can then be activated using an appropriate activation compound, such as a gold or palladium compound. The activated pure nickel microtool can then be deposited in an electroless plating bath, and nickel ions will be attracted to the activated areas of the pure nickel microtool. The microtool can be removed after an appropriate amount of time, depending on the desired thickness of the electroless nickel layer. Using this method, a microtool that has already been formed can be modified to increase its hardness according to an embodiment of the invention.

This invention has been described with reference to specific exemplary embodiments thereof. It will, however, be evident to persons having the benefit of this disclosure that various modifications and changes may be made to these embodiments without departing from the broader spirit and scope of the invention. The specification and drawings are accordingly to be regarded in an illustrative, rather than in a restrictive sense.

1.-10. (canceled)

11. A method comprising:
forming a mold including a pattern to pattern a substrate;
electrolessly depositing an electroless nickel layer over the mold;
depositing a metal layer over the electroless nickel layer; and
removing the mold from the electroless nickel layer.

12. The method of claim 11, wherein forming the mold comprises depositing a photoresist layer and using photolithography to create the pattern.

13. The method of claim 11, wherein forming the mold comprises depositing a silicon layer, and using photolithography to create the pattern.

14. The method of claim 11, wherein depositing a metal layer comprises electroplating.

15. The method of claim 11, wherein removing comprises manually removing the mold.

16. The method of claim 15, further comprising chemically removing the mold after manually removing the mold.

17. The method of claim 11, further comprising annealing the electroless nickel layer.

18. The method of claim 11, wherein the electroless nickel layer comprises a composite layer consisting of electroless nickel and a reinforcement constituent chosen from the group consisting of silicon carbide, aluminum oxide, diamond particles, and polytetrafluoroethylene (PTFE).

19. A method comprising:
providing a substrate core;
depositing a dielectric layer over the core; and
patterning the dielectric layer using a microtool having an electroless nickel outer layer.

20. The method of claim 19, wherein patterning comprises pressing the microtool against the dielectric layer.

21. The method of claim 19, further comprising:
depositing a seed layer over the dielectric layer; and
electroplating the dielectric layer to form interconnects in the dielectric layer.

22. The method of claim 20, wherein pressing comprises using a pushing jig to press the microtool against the dielectric layer.

23. The method of claim 21, further comprising curing the dielectric layer.

24. The method of claim 21, wherein electroplating the dielectric layer comprises:
electroplating the dielectric layer with copper; and
planarizing the dielectric layer.

25.-28. (canceled)

29. A method comprising:
forming a mold including a pattern to pattern a substrate;
depositing a nickel layer over the mold;
depositing a metal layer over said nickel layer, wherein said metal layer has a hardness less than that of said nickel layer; and
removing the mold from said nickel layer.

30. The method of claim 11, wherein forming the mold comprises depositing a silicon layer, and using photolithography to create the pattern.

31. The method of claim 25, wherein depositing a nickel layer comprises electroless deposition.

32. The method of claim 25, wherein depositing a metal layer comprises electroplating.

33. The method of claim 25, further comprising annealing said nickel layer.

34. The method of claim 25, wherein said nickel layer comprises a composite layer consisting of nickel and a reinforcement constituent chosen from the group consisting of silicon carbide, aluminum oxide, diamond particles, and polytetrafluoroethylene (PTFE).
